(19) United States
(12) Patent Application Publication
(10) Pub. No.: US 2018/0366553 A1
(43) Pub. Date: Dec. 20, 2018

(54) METHODS OF FORMING AN AIR GAP ADJACENT A GATE STRUCTURE OF A FINFET DEVICE AND THE RESULTING DEVICES

(71) Applicant: GLOBALFOUNDRIES Inc., Grand Cayman (KY)

(72) Inventors: Hui Zang, Guilderland, NY (US); Bala Haran, Watervliet, NY (US); Xuan Tran, Clifton Park, NY (US); Suryanarayana Kalaga, Mechanicville, NY (US)

(21) Appl. No.: 15/624,332

(22) Filed: Jun. 15, 2017

(51) Int. Cl. H01L 29/49; H01L 23/535; H01L 29/78; H01L 29/06; H01L 29/66; H01L 21/768

(52) U.S. Cl. CPC H01L 29/4991; H01L 23/535; H01L 29/7851; H01L 29/0649; H01L 21/76895; H01L 29/66545; H01L 21/76805; H01L 21/7682; H01L 29/66795

(57) ABSTRACT

A method that includes forming an isolation material adjacent a fin, forming a sidewall spacer around a portion of the fin and above the isolation material and forming first and second conductive source/drain contact structures adjacent the sidewall spacer, wherein each of the first and second conductive source/drain contact structures has a side surface positioned proximate the sidewall spacer. In this example, the method further includes, after forming the source/drain contact structures, removing at least a portion of the sidewall spacer and forming a gate cap that is positioned above a final gate structure for the device, wherein the gate cap contacts the source/drain contact structures, and wherein an air gap is formed at least on opposite sides of the final gate structure above an active region of the device.

### BACKGROUND OF THE INVENTION

### 1. Field of the Invention

The present disclosure generally relates to the fabrication of integrated circuits, and, more particularly, to various methods of forming an air gap adjacent a gate structure of a FinFET device and the resulting devices.

### 2. Description of the Related Art

In modern integrated circuits, such as microprocessors, storage devices and the like, a very large number of circuit elements, especially transistors, are provided on a restricted chip area. Transistors come in a variety of shapes and forms, e.g., planar transistors, FinFET transistors, nanowire devices, etc. The transistors are typically either NMOS (NFET) or PMOS (PFET) type devices wherein the “N” and “P” designation is based upon the type of dopants used to create the source/drain regions of the devices. So-called CMOS (Complementary Metal Oxide Semiconductor) technology or products refers to integrated circuit products that are manufactured using both NMOS and PMOS transistor devices. Irrespective of the physical configuration of the transistor device, each transistor device comprises laterally spaced apart drain and source regions that are formed in a semiconductor substrate, a gate electrode structure positioned above the substrate and between the source/drain regions, and a gate insulation layer positioned between the gate electrode and the substrate. Upon application of an appropriate control voltage to the gate electrode, a conductive channel region forms between the drain region and the source region and current flows from the source region to the drain region.

A conventional FET is a planar device wherein the entire channel region of the device is formed parallel and slightly below the planar upper surface of the semiconducting substrate. To improve the operating speed of planar FETs, and to increase the density of planar FETs on an integrated circuit product, device designers have greatly reduced the physical size of planar FETs over the past decades. More specifically, the channel length of planar FETs has been significantly decreased, which has resulted in improving the switching speed and in lowering operation currents and voltages of planar FETs. However, decreasing the channel length of a planar FET also decreases the distance between the source region and the drain region. In some cases, this decrease in the separation between the source and the drain makes it difficult to efficiently inhibit the electrical potential of the source region and the channel from being adversely affected by the electrical potential of the drain. This is sometimes referred to as a so-called short channel effect, wherein the characteristic of the planar FET as an active switch is degraded.

In contrast to a planar FET, there are so-called 3D devices, such as an illustrative FinFET device, which is a three-dimensional structure. FIG. 1 is a perspective view of an illustrative prior art FinFET semiconductor device 10 that is formed above a semiconductor substrate 12 wherein the fins 14 of the device 10 are made of the material of the substrate 12, e.g., silicon. The device 10 includes a plurality of fin-formation trenches 13, three illustrative fins 14, a gate structure 16, a sidewall spacer 18 and a gate cap layer 20. The spacer 18 is typically made of silicon nitride, but in some cases it may be made of a material having a lower dielectric constant (k) than that of silicon nitride. An insulating material 17, e.g., silicon dioxide, provides electrical isolation between the fins 14. The gate structure 16 is typically comprised of a layer of insulating material (not separately shown), e.g., a layer of high-k insulating material, and one or more conductive material layers that serve as the gate electrode for the device 10. The fins 14 have a three dimensional configuration: a height H, a width W and an axial length L. The axial length L corresponds to the gate length of the device, i.e., the direction of current travel in the device 10 when it is operational. The gate width of the device 10 is orthogonal to the gate length direction. The portions of the fins 14 covered by the gate structure 16 are the channel regions of the FinFET device 10. The portions of the fins 14 that are positioned outside of the spacers 18 will become part of the source/drain regions of the device 10.

FIG. 2 depicts an illustrative prior art FinFET device 10A that includes an air gap 23 formed in a spacer 18A of the device 10A. Such a spacer 18A is sometimes referred to as an “air gap spacer.” The device 10A has several common features to the device 10 shown in FIG. 1. Accordingly, common reference numbers will be used in FIG. 2 where appropriate. FIG. 2 contains a simplistic plan view of the device 10A to show where various cross-sectional views in FIG. 2 are taken. The cross-sectional view X-X is taken through an illustrative fin 14 (in the gate-length direction of the device 10A). The cross-sectional view Y-Y is taken between adjacent fins 14 in a direction that corresponds to the gate-length direction of the device 10A. The cross-sectional view Z-Z is taken through a spacer 18A formed adjacent the gate structure of the device 10A in a direction that corresponds to the gate-width direction of the device 10A. With reference to FIG. 2, the FinFET device 10A comprises an illustrative gate structure 16, i.e., a gate insulation layer (not separately shown) and a gate electrode (not separately shown), a gate cap layer 20 (e.g., silicon nitride), a sidewall spacer 18A (e.g., silicon nitride), an epi semiconductor material 19 formed on the fins 14 in the source/drain regions of the device and simplistically depicted source/drain regions, i.e., the regions positioned laterally outside of the spacer 18A, and illustrative conductive source/drain contact structures 21, e.g., trench silicide structures, that are provided so as to have a means to establish a conductive electrical path to the source/drain regions of the device 10A. As noted above, the spacer 18A also comprises an air gap 23 that was intentionally formed in the spacer 18A. The air gap 23 is defined by an uppermost surface 23A and a lowermost surface 23B. The air gap 23 typically extends around the entire perimeter of the gate structure 16, just like the spacer 18A, but that may not be the case in all devices.

As noted above, the spacer on a FinFET device is typically made of silicon nitride which has a relatively high dielectric constant (k) value of about 7-8. As a result of the physical configuration of the transistor 10A, a capacitor is defined between the gate electrode of the gate structure 16 and the source/drain contact structures 21 (i.e., a gate-to-S/D contact capacitor), wherein the gate electrode functions as one of the conductive plates of the capacitor, the source/drain contact structures 21 function as the other conductive plate of the capacitor and the spacer is positioned between the two conductive plates. This gate-to-S/D contact capacitor is parasitic in nature in that this capacitor must charge and discharge every time the device 10A is turned on and off, all of which results in delaying the switching speed of the device 10A.

Device designers have made efforts to reduce the parasitic gate-to-S/D contact capacitor. For example, some process flows have been developed for forming the spacer of a material having a lower k value than that of silicon nitride so as to reduce the capacitance. Another technique that has been employed is to form the air gap 23 in the spacer 18A so as to reduce the k value of the spacer. The air gap 23 is typically formed prior to the formation of the source/drain contact structures 21. As shown FIG. 2, the spacer 18A has a generally stepped configuration in that it has a smaller vertical height 18X where it is located above the fin 14 than the vertical height 18Y of the spacer 18A where it is located above the isolation material 17. In contrast, the air gap 23 typically has a substantially uniform height or length 23H (defined by the distance between the surfaces 23A and 23B) in the portion of the spacer 18A positioned above the fin 14 (see view X-X) as well as the portion of the spacer 18A positioned above the isolation material 17 in the area between adjacent fins 14 (see view Y-Y and Z-Z). That is, as shown in the views Y-Y and Z-Z, the air gap 23 is not formed adjacent the lower portion 16L of the gate structure 16 (not shown in the view Z-Z) in the sections of the gate structure 16 that are not formed above the fin 14. Stated another way, while the air gap 23 is positioned adjacent substantially the entire vertical height 16X (view X-X) of the gate structure 16 where it crosses the fin 14, the air gap 23 is not positioned adjacent a significant portion of the entire height 16Y (view Y-Y) of the gate structure 16 in the portions of the gate structure 16 positioned above the isolation material 17. Thus, while formation of such a uniform height air gap 23 may be beneficial in reducing the gate-to-S/D contact capacitor, further reductions in the gate-to-S/D contact capacitor are needed so as to improve device performance.

The present disclosure is directed to various methods of forming an air gap adjacent a gate structure of a FinFET device and the resulting devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the present disclosure is directed to various methods of forming an air gap adjacent a gate structure of a FinFET device and the resulting devices. One illustrative method disclosed herein includes, among other things, forming an isolation material adjacent a fin, forming a sidewall spacer around a portion of the fin and above the isolation material and forming first and second conductive source/drain contact structures adjacent the sidewall spacer, wherein each of the first and second conductive source/drain contact structures comprise a side surface positioned proximate the sidewall spacer. In this example, the method further includes, after forming the first and second conductive source/drain contact structures, removing at least a portion of the sidewall spacer and forming a final gate cap that is positioned above a final gate structure for the device, wherein the final gate cap contacts the first and second conductive source/drain contact structures, and wherein an air gap is formed at least on opposite sides of the final gate structure above an active region of the device, the air gap being vertically bounded by at least a bottom surface of the final gate cap, an upper surface of the fin and an upper surface of the isolation material, the air gap being laterally bounded at least by portions of the side surfaces of the first and second conductive source/drain contact structures.

One illustrative device disclosed herein includes, among other things, a gate structure positioned above a portion of a fin and above an isolation material formed adjacent the fin, an etch stop layer positioned on and in contact with all of the side surfaces of the gate structure and first and second conductive source/drain contact structures, each of which comprise a side surface positioned proximate the gate structure. In this example, the device further includes a gate cap that is positioned above the gate structure and contacts the first and second conductive source/drain contact structures, wherein an air gap is formed at least on opposite sides of the gate structure above an active region of the device, the air gap being vertically bounded by at least a bottom surface of the gate cap, an upper surface of the fin and an upper surface of the isolation material, the air gap being laterally bounded by the etch stop layer and side surfaces of the first and second conductive source/drain contact structures.

### BRIEF DESCRIPTION OF THE DRAWINGS

The disclosure may be understood by reference to the following description taken in conjunction with the accompanying drawings, in which like reference numerals identify like elements, and in which:

FIG. 1 is a simplistic depiction of an illustrative prior art FinFET device;

FIG. 2 depicts one illustrative example of a prior art FinFET device comprised of an air gap positioned adjacent the gate structure of the device; and

FIGS. 3-14 depict various novel methods disclosed herein for forming an air gap adjacent a gate structure of a FinFET device and the resulting novel devices.

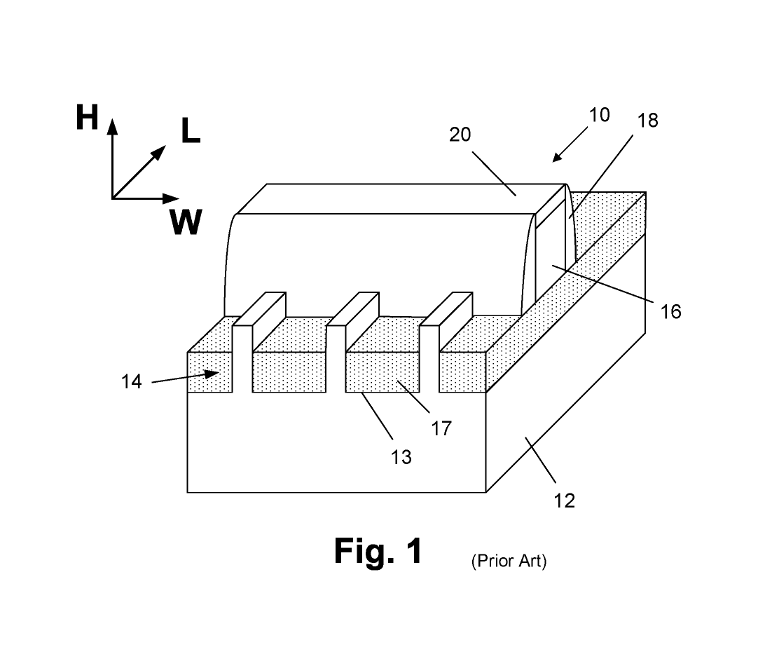

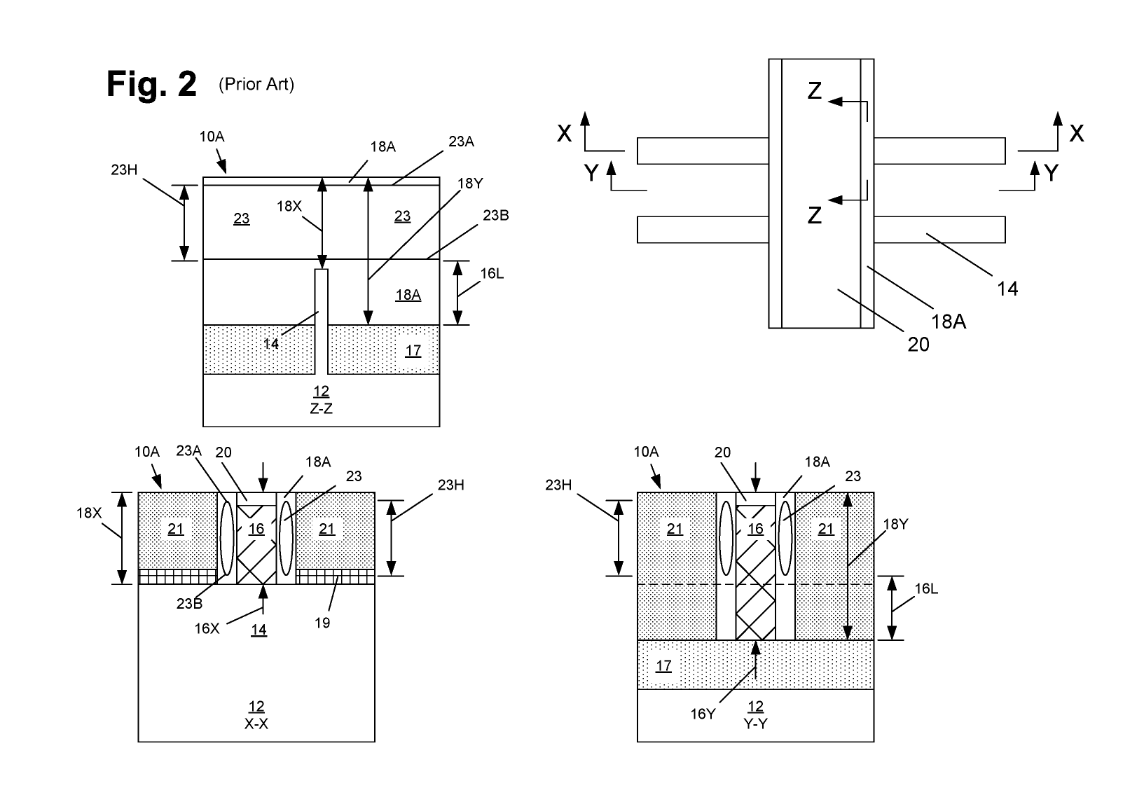

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The present disclosure generally relates to various novel methods of forming an air gap adjacent a gate structure of a FinFET device and the resulting novel devices. As will be readily apparent to those skilled in the art upon a complete reading of the present application, the present method is applicable to a variety of products, including, but not limited to, logic products, memory products, etc. With reference to the attached figures, various illustrative embodiments of the methods and devices disclosed herein will now be described in more detail.

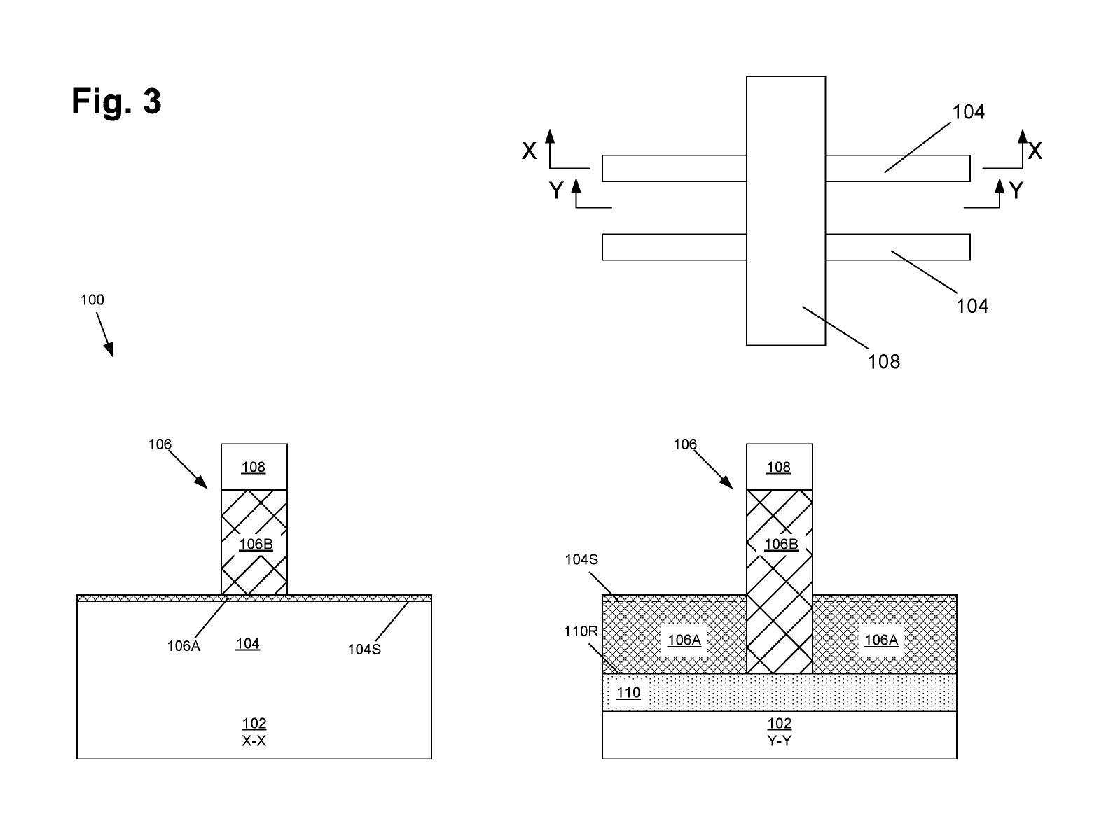

FIGS. 3-14 depict various novel methods disclosed herein for forming an air gap adjacent a gate structure of a FinFET device 100 and the resulting devices. FIG. 3 contains a simplistic plan view of the device 100 to show where various cross-sectional views in the following drawings are taken. The cross-sectional view X-X is taken through an illustrative fin 104 (in the gate-length direction of the device 100). The cross-sectional view Y-Y is taken between adjacent fins 104 in a direction that corresponds to the gate-length direction of the device 100.

The illustrative device 100 will be formed in and above a semiconductor substrate 102. The transistor devices depicted herein may be either NMOS or PMOS transistors. The gate electrode and gate insulation layer of the gate structures of such devices may be formed by performing well-known gate-first or replacement gate processing techniques.

Additionally, various doped regions, e.g., halo implant regions, doped source/drain regions, well regions and the like, are not depicted in the attached drawings. The substrate 102 may have a variety of configurations, such as the depicted bulk silicon configuration. The substrate 102 may also have a silicon-on-insulator (SOI) configuration that includes a bulk silicon layer, a buried insulation layer and an active layer, wherein semiconductor devices are formed in and above the active layer. The substrate 102 may be made of silicon or it may be made of materials other than silicon. Thus, the terms “substrate” or “semiconductor substrate” should be understood to cover all semiconducting materials and all forms of such materials. The various components and structures of the device disclosed herein may be formed using a variety of different materials and by performing a variety of known techniques, e.g., a chemical vapor deposition (CVD) process, an atomic layer deposition (ALD) process, a thermal growth process, spin-coating techniques, etc. The thicknesses of these various layers of material may also vary depending upon the particular application.

FIG. 3 depicts the device 100 after several process operations were performed. First, one or more etching processes, e.g., anisotropic etching processes, were performed through a patterned fin-formation etch mask (not shown) to form a plurality of fin-formation trenches and thereby define a plurality of fin structures 104. The patterned fin-formation hard mask may be comprised of one or more layers of material and it may be formed to any desired overall thickness. As one example, the patterned fin-formation hard mask may be comprised of a relatively thin layer of silicon dioxide and a relatively thicker layer of silicon nitride.

With continuing reference to FIG. 3, the width and height of the fin structures 104 may vary depending upon the particular application. Additionally, the overall size, shape and configuration of the fin-formation trenches and the fin structures 104 may vary depending on the particular application. In the illustrative examples depicted in the attached drawings, the fin-formation trenches and the fins 104 are all depicted as having a uniform size and shape. However, such uniformity in the size and shape of the trenches and the fins 104 is not required to practice at least some aspects of the inventions disclosed herein. In the attached figures, the fin-formation trenches are depicted as having been formed by performing an anisotropic etching process that results in the fin structures 104 having a schematically (and simplistically) depicted, generally rectangular configuration. In an actual real-world device, the sidewalls of the fins 104 may be somewhat outwardly tapered (i.e., the fins may be wider at the bottom of the fin than they are at the top of the fin), although that configuration is not depicted in the attached drawings. Thus, the size and configuration of the fin-formation trenches and the fins 104, and the manner in which they are made, should not be considered a limitation of the present invention. For ease of disclosure, only the substantially rectangular trenches and fins 104 will be depicted in the subsequent drawings. Moreover, the device 100 may be formed with any desired number of fins 104. In the example depicted herein, the device 100 will be comprised of two of the illustrative fins 104.

With continuing reference to FIG. 3, after formation of the fins 104, a layer of insulating material 110 (e.g., silicon dioxide) was deposited so as to overfill the fin-formation trenches and after at least one process operation, such as a chemical mechanical polishing (CMP) process, was performed to planarize the upper surface of the layer of insulating material 110 with the upper surface 104S of the fins 104. Thereafter, a recess etching process was performed on the layer of insulating material 110 to reduce its thickness within the fin-formation trenches such that it has a recessed upper surface 110R that is positioned at a level that is below the level of the upper surface 104S of the fins 104. Next, a sacrificial gate structure 106 (comprised of a sacrificial gate insulation layer 106A and a sacrificial gate electrode 106B) and a gate cap 108 were formed on the device 100. In one illustrative example, the sacrificial gate insulation layer 106A may be formed by performing an oxidation process so as to oxidize the exposed portions of the fin 104 above the recessed upper surface 110R of the layer of insulating material 110. At that point, the material for the gate electrode 106B, e.g., amorphous silicon, polysilicon, etc., was blanket-deposited across the substrate 102 and its upper surface was subjected to a CMP process to planarize the upper surface of the deposited layer of material. Thereafter, the material for the gate cap 108, e.g., silicon nitride, was blanket-deposited across the substrate 102 above the layer of material for the sacrificial gate electrode 106B. At that point, a patterned etch mask layer (not shown) was formed above the layer of gate cap material. Then, an etching process was performed though the patterned etch mask so as to pattern the layer of gate cap material, thereby resulting in the gate cap 108 depicted in FIG. 3. Then, the patterned etch mask was removed and an etching process was performed to remove exposed portions of the gate electrode material layer so as to result in the patterned sacrificial gate electrode structure 106B depicted in FIG. 3. As indicated, at this point in the process, the sacrificial gate insulation layer 106A remains positioned on the fin 104 in the portions of the fin 104 that are not covered by the gate structure 106.

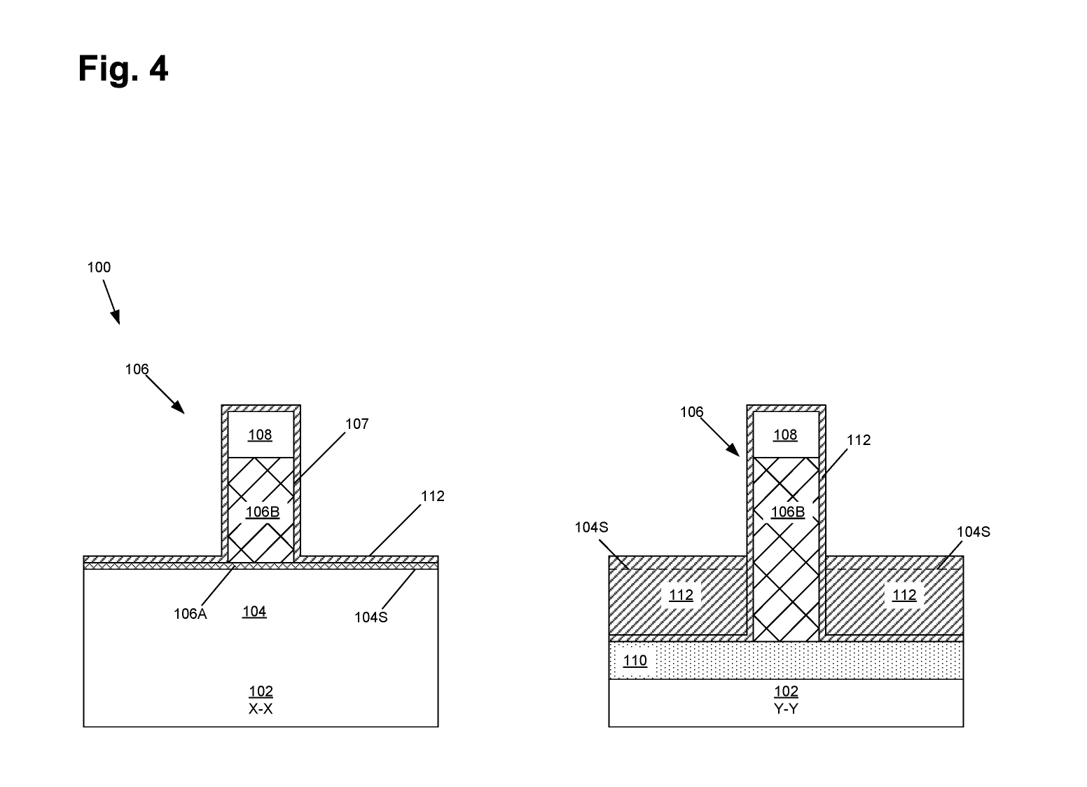

FIG. 4 depicts the device 100 after a conformal etch stop layer 112 was formed on the device 100 by performing a conformal deposition process, e.g., a conformal ALD deposition process. More specifically, the conformal etch stop layer 112 was formed on and in contact with all side surfaces 107 of the sacrificial gate electrode 106B, the gate cap 108 and the sacrificial gate insulation layer 106A. The etch stop layer 112 may be comprised of a variety of different materials, such as, for example, a high-k (k greater than 10) insulation material (where k is the relative dielectric constant), hafnium oxide, Al₂O₃, Hf₂AlO₂, HfLaO₂, HfNO, AlNO, etc. The thickness of the etch stop layer 112 may also vary depending upon the particular application, e.g., 1-10 nm.

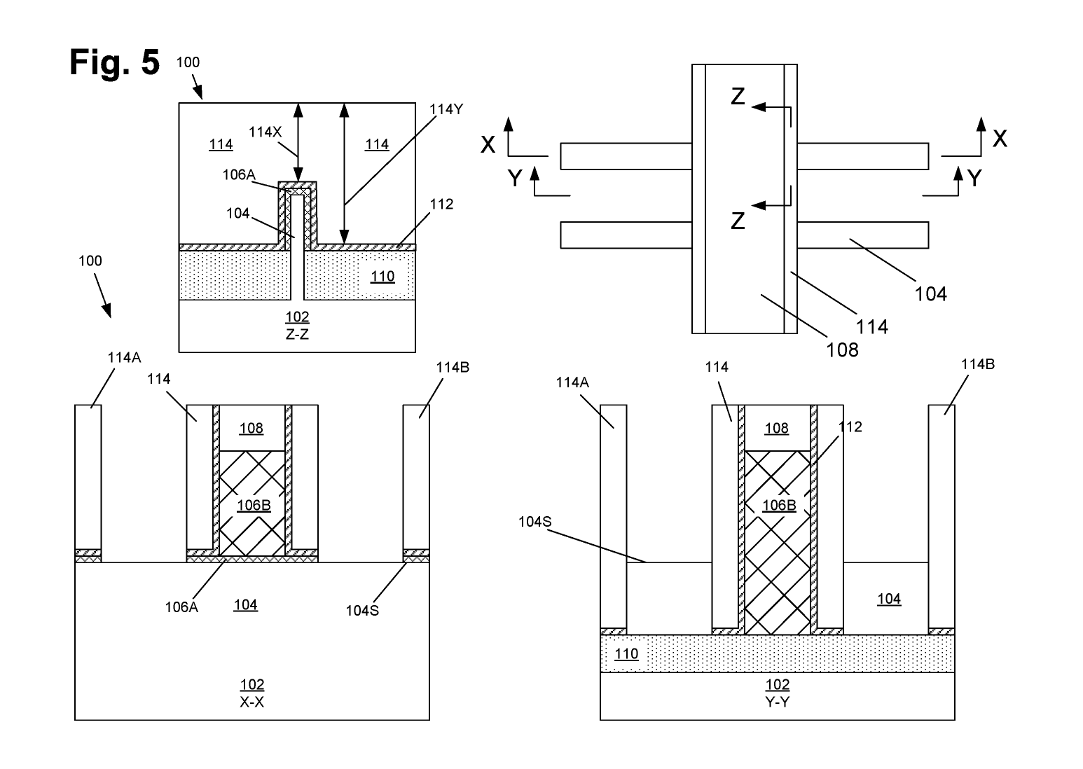

FIG. 5 depicts the device 100 after several process operations were performed. First, a sidewall spacer 114 was formed adjacent the sacrificial gate structure 106 and around the entire perimeter of the gate structure. FIG. 5 contains a cross-sectional view Z-Z that is taken through the spacer 114 in a direction that corresponds to the gate-width direction of the device 100. No attempt has been made to show the etch stop layer 112 in the simplistic plan view. Also depicted in FIG. 5 are sidewall spacers 114A and 114B that are formed adjacent other gate structures (not shown) that are formed above the substrate 102. As shown in FIG. 5, the spacer 114 has a generally stepped configuration in that it has a smaller vertical height 114X where it is located above the fin 104 than the vertical height 114Y of the spacer 114 where it is located above the isolation material 110. The sidewall spacer 114 may be formed by depositing a conformal layer of spacer material (not shown) above the substrate 102 and thereafter performing an anisotropic etching process to remove horizontally positioned portions of the layer of spacer material. The spacer 114 may be of any desired thickness (as measured at its base). The spacer 114 may be comprised of a variety of different materials, e.g., silicon nitride, SiNC, SiN, SiCO, and SiNOC, etc., but it should be made of a material that exhibits good etch selectivity to the material of the etch stop layer 112. After the spacer 114 was formed, an etching process was performed to remove the exposed portions of the etch stop layer 112 and thereafter exposed portions of the sacrificial gate insulation layer 106A. These process operations expose the portions of the fins 104 positioned between the spacers formed on adjacent devices.

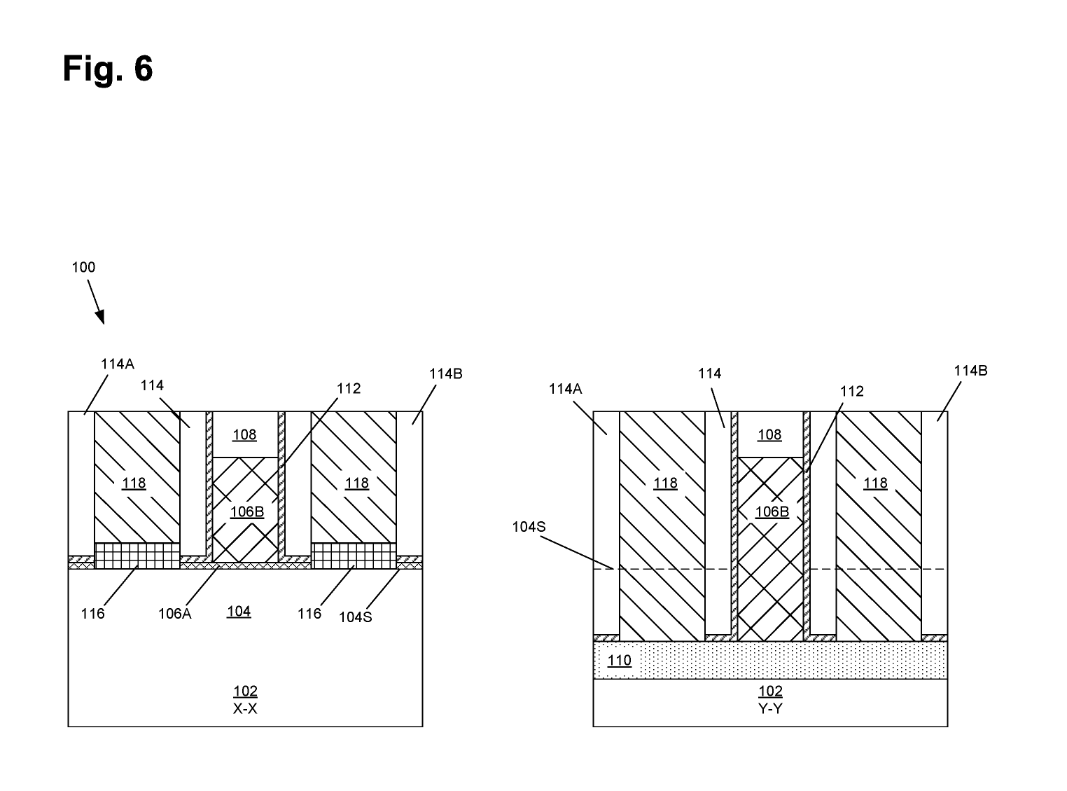

FIG. 6 depicts the device 100 after several process operations were performed. First, an epi semiconductor material 116 was formed on the exposed portions of the fins 104 by performing an epitaxial growth process. The epi material 116 may be formed to any desired thickness. However, it should be understood that the epi material 116 need not be formed in all applications. Next, a layer of insulating material 118 was blanket-deposited on the device 100 so as to overfill the openings above the epi material 116. At that point, a CMP process was performed to planarize the layer of insulating material 118 using the gate caps 108 as a polish stop layer. The layer of insulating material 118 may be made from a variety of insulating materials, e.g., silicon dioxide, SiCO, a low-k material (k value of 8 or less), etc.

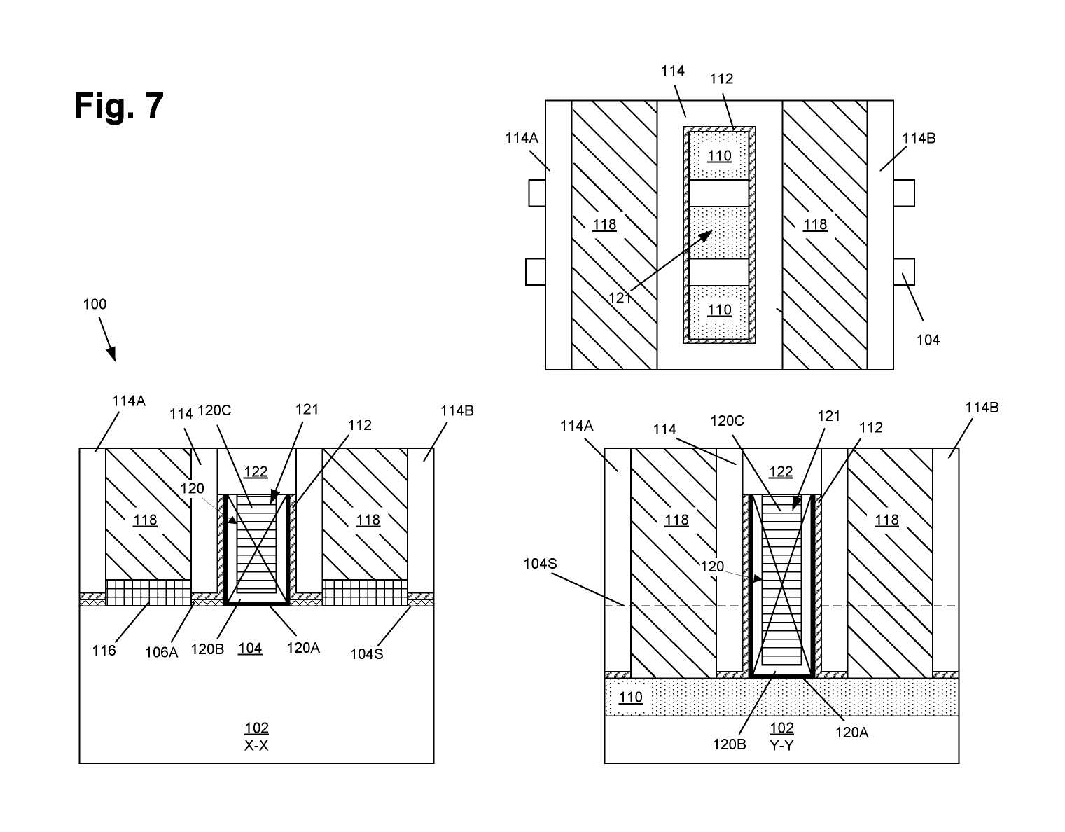

FIG. 7 depicts the device 100 after several process operations were performed including the formation of an illustrative and representative replacement gate structure 120 for the device 100. Initially, the gate cap 108 (see FIG. 6) and the sacrificial gate electrode 106B (see FIG. 6) were removed by performing one or more etching processes. Thereafter, the portion of the sacrificial gate insulation layer 106A (see FIG. 6) between the etch stop layer 112 was removed by performing a selective etching process. These operations result in the formation of a replacement gate cavity 121, wherein the sides of the gate cavity 121 are defined by the remaining portions of the etch stop layer 112. FIG. 7 contains a simplistic plan view of the device 100 showing the formation of the gate cavity 121. Note that formation of the gate cavity 121 exposes portions of the isolation material 110 and portions of the fins 104. The isolation material 110 defines the bottom of the gate cavity 121.

Next, the materials for the replacement gate structure 120 were sequentially formed on the device 100 and in the gate cavity 121. For example, a first conformal deposition process was performed to form a gate insulation layer 120A in the gate cavity 121, followed by performing a second conformal deposition process to form an illustrative work function adjusting metal layer 120B (e.g., titanium nitride, TiC, TiAlC, W, Al, etc. depending upon the type of device (N or P) being manufactured) on the gate insulation layer 120A and in the gate cavity 121. At that point, a blanket deposition process was performed to form a bulk conductive material 120C on the work function adjusting metal layer 120B. The bulk conductive material 120C (e.g., tungsten, aluminum, polysilicon, etc.) was formed so as to over-fill the remaining portion of the gate cavity 121. Thereafter, one or more CMP processes were performed so as to remove excess portions of the gate insulation layer 120A, the work function adjusting metal layer 120B and the bulk conductive material 120C that are positioned above the layer of insulating material 118 and outside of the gate cavity 121. At that point, one or more recess etching processes were performed to recess the vertical height of the materials of the replacement gate structure 120 so as to make room for a replacement gate cap 122. The replacement gate cap 122 was formed by blanket depositing a layer of the material for the replacement gate cap 122 above the device and in the space above the recessed gate material for the gate structure 120. At that point, another CMP process was performed using the layer of insulating material 118 as a polish-stop so as to remove excess amounts of the material for the replacement gate cap 122. At this point in the processing, the replacement gate structure 120 with the replacement gate cap 122 has been formed on the device 100. Of course, the materials of construction for the replacement gate structure 120 may vary depending upon whether the device 100 is an N-type device or a P-type device. Additionally, the replacement gate structure 120 may have a different number of layers of material depending upon the type of device under construction, e.g., the replacement gate structure 120 for an N-type device may comprise more layers of conductive material than are present in the replacement gate structure 120 for a P-type device. The gate insulation layer 120A may be comprised of a variety of different materials, such as, for example, silicon dioxide, a so-called high-k (k greater than 10) insulation material (where k is the relative dielectric constant), etc. In some cases, the gate insulation layer 120A may be comprised of a material that is different from, and selectively etchable with respect to, the etch stop layer 112. In other applications, the gate insulation layer 120A and the etch stop layer 112 may be made of the same material. The replacement gate cap 122 may be made of a variety of different materials, e.g., silicon nitride, SiCN, SiN/SiCN, SiOC, SiOCN, etc. In one illustrative embodiment, the replacement gate cap 122 may be made of a material that exhibits good etch selectivity relative to the material of the spacer 114.

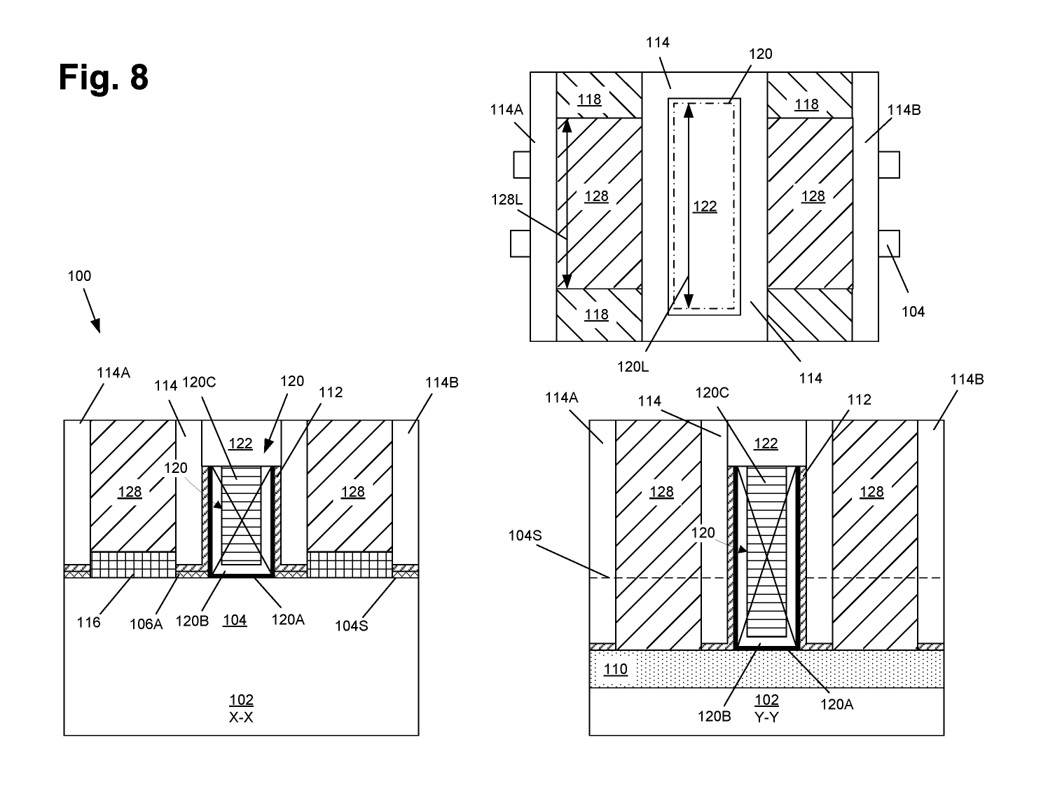

FIG. 8 depicts the device 100 after several process operations were performed. First, an etching process was performed to remove at least portions of the layer of insulating material 118 where conductive source/drain contact structures will be formed. This process exposes the epi semiconductor material 116 on the fins 104 in the source/drain regions of the device. Next, conductive source/drain contact structures 128 were formed on the device 100 so as to provide a means to electrically contact the source/drain regions of the device 100. The conductive source/drain contact structures 128 may be made from a variety of conductive materials, e.g., tungsten, trench silicide materials, etc. As depicted in the view Y-Y, the conductive source/drain contact structures 128 are also positioned above the isolation material 110. The conductive source/drain contact structures 128 extend for a desired axial length 128L in the gate width direction of the device as shown in the simplistic plan view in FIG. 8. The length 128L corresponds to the length of the active region in the gate width direction. The plan view also depicts the replacement gate structure 120 in dashed lines under the gate cap 122. The axial length 120L of the replacement gate structure 120 is typically greater than the axial length 128L of the conductive source/drain contact structures 128 so as to permit a gate contact structure (not shown) to be made to the replacement gate structure 120 at a location that is not above the active regions, i.e., the gate contact structure is typically formed in an area above the isolation material 110.

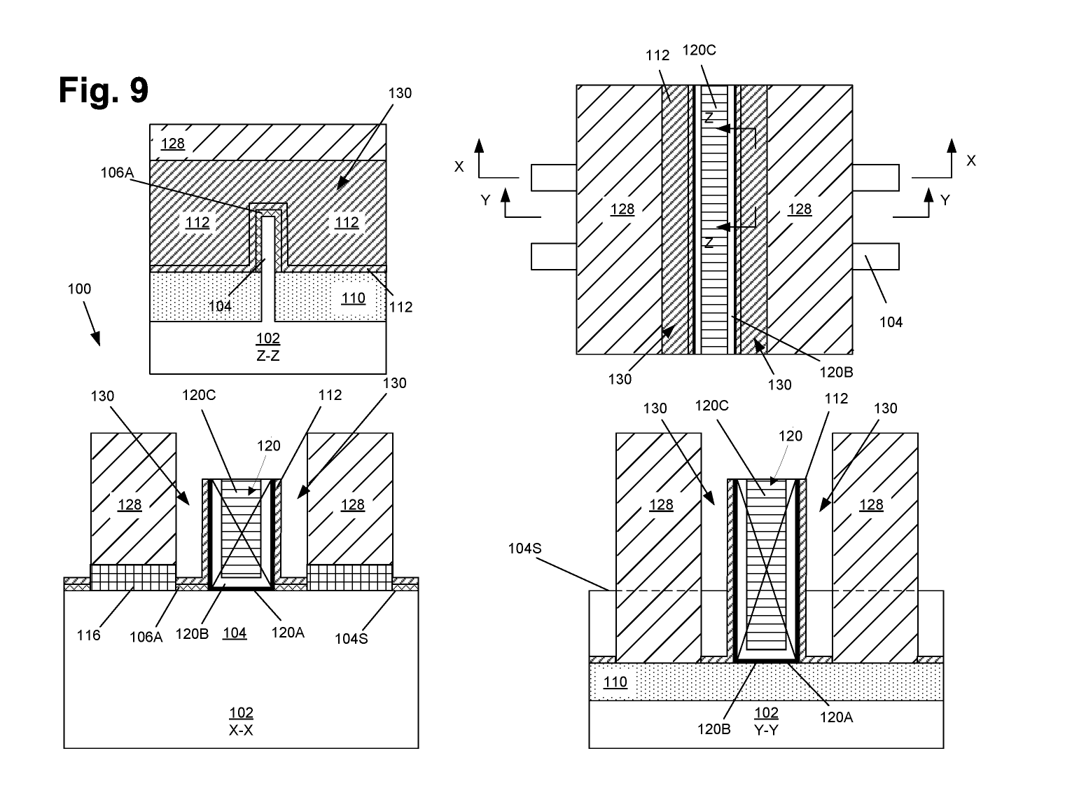

FIG. 9 depicts the device 100 after one or more etching processes were performed to selectively remove the replacement gate cap 122 and substantially the entirety of the spacer 114 (and 114A, 114B as well) relative to the surrounding materials. This results in the formation of gaps 130 adjacent the replacement gate structure 120 above the fin 104 and above the isolation region 110 as shown in the views Y-Y and Z-Z. The cross-sectional view Z-Z is taken through the gaps 130 in a direction that corresponds to the gate-width direction of the device 100. The simplistic plan view in FIG. 9 is not meant to agree in all details with respect to the previous plan views in other Figures.

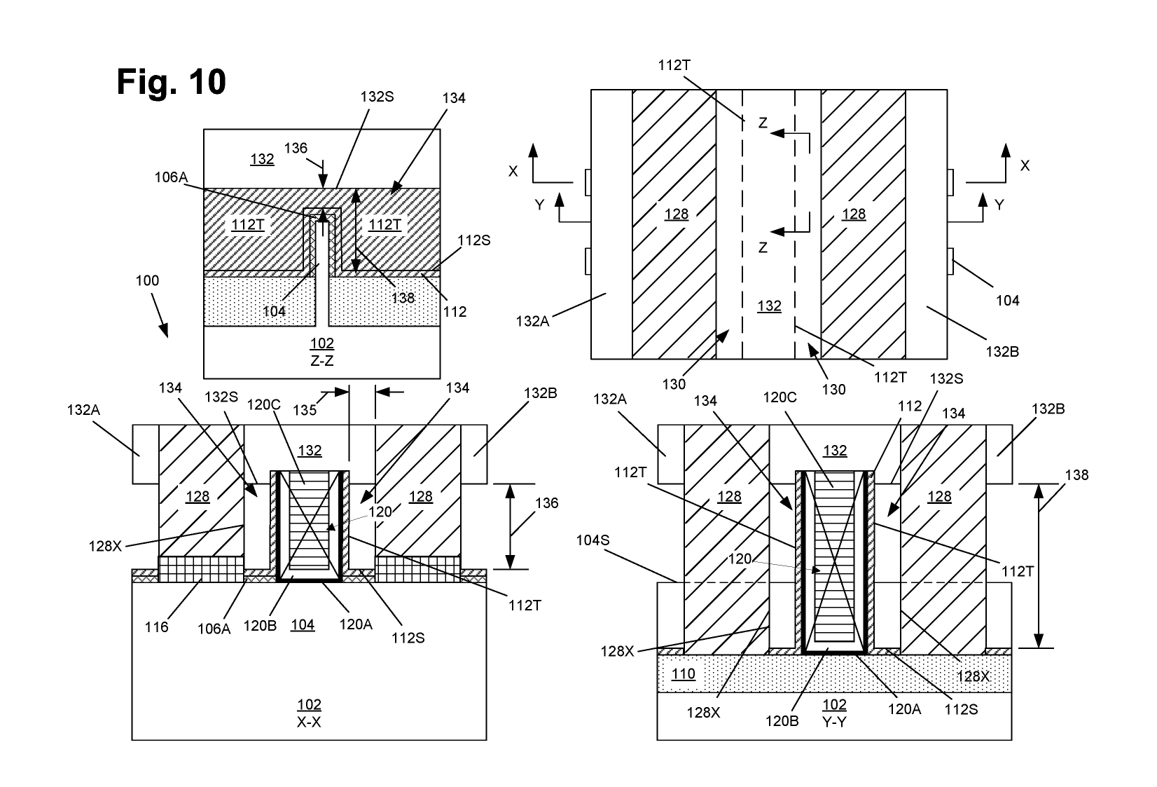

FIG. 10 depicts the device 100 after a final gate cap 132 was formed by blanket depositing a layer of the material for the replacement gate cap 132 above the device, above the replacement gate structure 120 and above the gap 130. The material for the final gate cap 132 was deposited in such a manner that it “pinches off” and does not fill the entirety of the gap 130. Also depicted are portions of the final gate caps 132A, 132B that are formed on adjacent devices. This process results in the formation of an air gap 134 adjacent the gate structure 120 for the device. In one embodiment, the air gap 134 extends around the entire perimeter of the gate structure 120. The final gate cap 132 may be made of a variety of different materials, e.g., silicon nitride, SiCN, etc. In this illustrative example, the air gap 134 is laterally bounded above the active region by at least the side surfaces 112T of the etch stop layer 112 that extends around the entire perimeter of the gate structure 120 and side surfaces 128X of the conductive source/drain contact structures 128 for the entire axial length 128L of the conductive source/drain contact structures 128. Beyond the ends of the conductive source/drain contact structures 128, the air gap 134 is bounded on the outside by insulating material 118 (not shown in FIG. 10) that is positioned around the ends of the gate prior to removing the spacer 114. The air gap 134 is bounded vertically by a lower surface 132S of the final gate cap 132, the upper surface 112S of the etch stop layer 112, the upper surface of the fins 104 and the isolation material 110. The air gap 134 has a generally stepped configuration in that it has a smaller vertical height 136 where it is located above the fin 104 than the vertical height 138 of the air gap 134 where it is located above the isolation material 110 (note that the drawings are not to scale). In this embodiment, the air gap 134 has a lateral width 135 (in the gate length direction of the device) that corresponds approximately to the lateral width of the spacer 114. Thus, using the methods disclosed herein, an air gap 134 may be formed that extends for substantially the entire vertical height of the gate structure 120 at locations above the fin 104 as well as at locations where the gate structure 120 is positioned above the isolation material 110. This novel device configuration should be helpful in reducing the impacts of the undesirable gate(120)-to-conductive source/drain contact structures (128) capacitor as it is charged and discharged on each on-off cycling of the device 100.

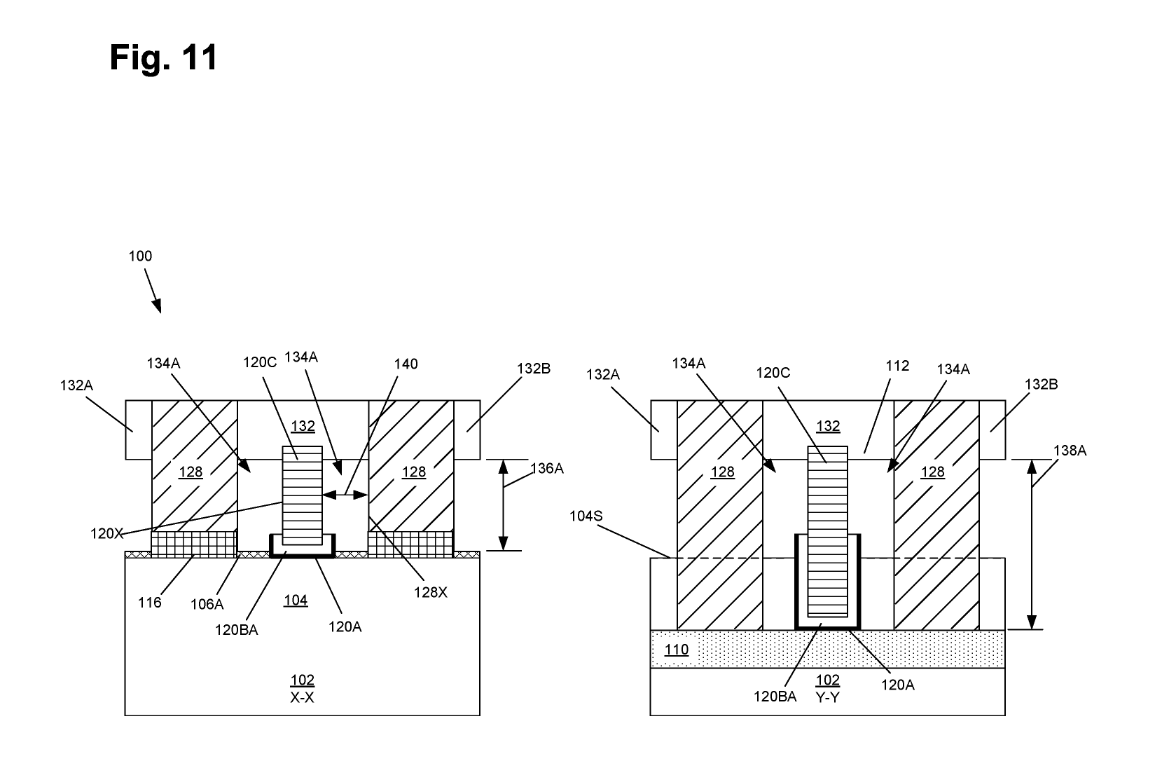

FIG. 11 depicts an alternative embodiment of the device 100 disclosed herein. In this embodiment, at some point in the process flow where the materials for the replacement gate structure were exposed, e.g., after the step shown in FIG. 9, the etch stop layer 112 may be removed, and all of the gate materials except the bulk conductive material 120C may be recessed by any desired amount. As shown in FIG. 11, this results in the formation of an air gap 134A that is bounded laterally above the active region by the side surface 120X of the bulk conductive material 120C and the side surfaces 128X of the conductive source/drain contact structures 128. This air gap 134A has a slightly larger lateral width 140 as compared to the lateral width 135 of the air gap 134. The dimensions 136A, 138A for the air gap 134A are slightly larger than the corresponding dimensions 136, 138 for the air gap 134 due to the removal of the etch stop layer 112.

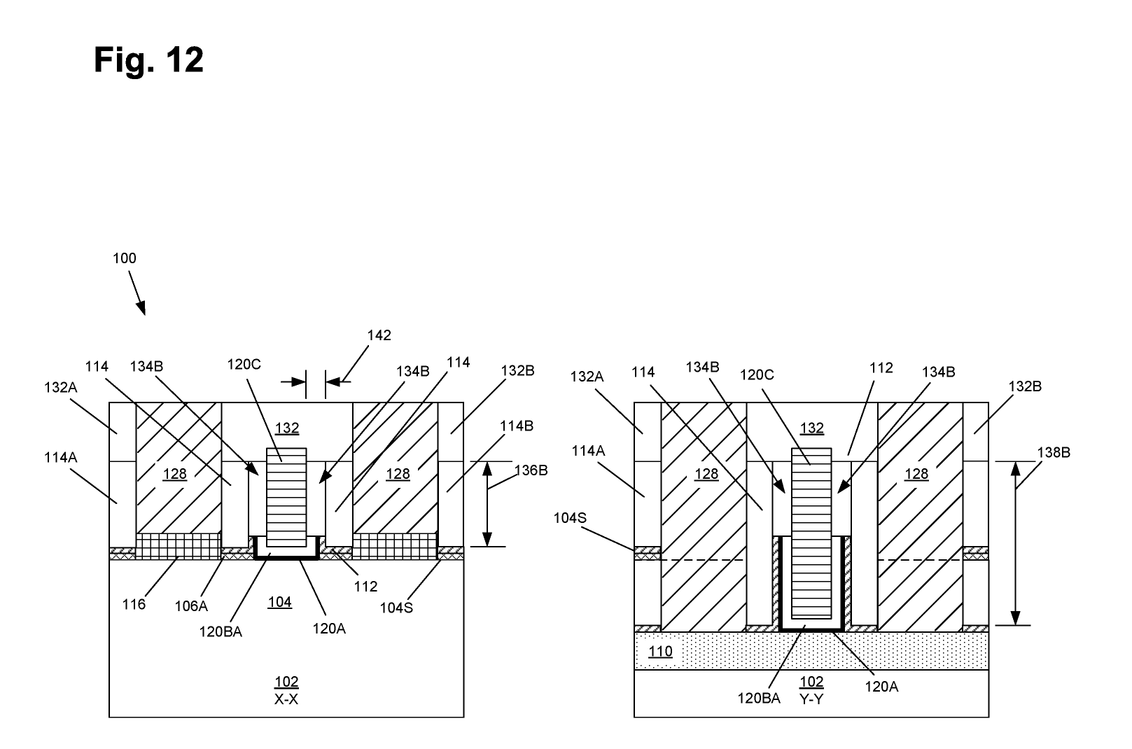

FIG. 12 depicts an alternative embodiment of the device 100 disclosed herein. In this embodiment, the spacer 114 is not removed. That is, at some point in the process flow where the materials for the replacement gate structure were exposed and prior to the removal of the spacer 114, e.g., after the step shown in FIG. 5, the etch stop layer 112 and all of the gate materials except the bulk conductive material 120C may be recessed by any desired amount. As shown in FIG. 12, this results in the formation of an air gap 134B that is bounded laterally above the active region by the spacer 114 and the bulk conductive material 120C. This air gap 134B has a slightly smaller lateral width 142 as compared to the lateral width 135 of the air gap 134. The dimensions 136B, 138B for the air gap 134B should be approximately the same as the corresponding dimensions 136, 138 for the air gap 134.

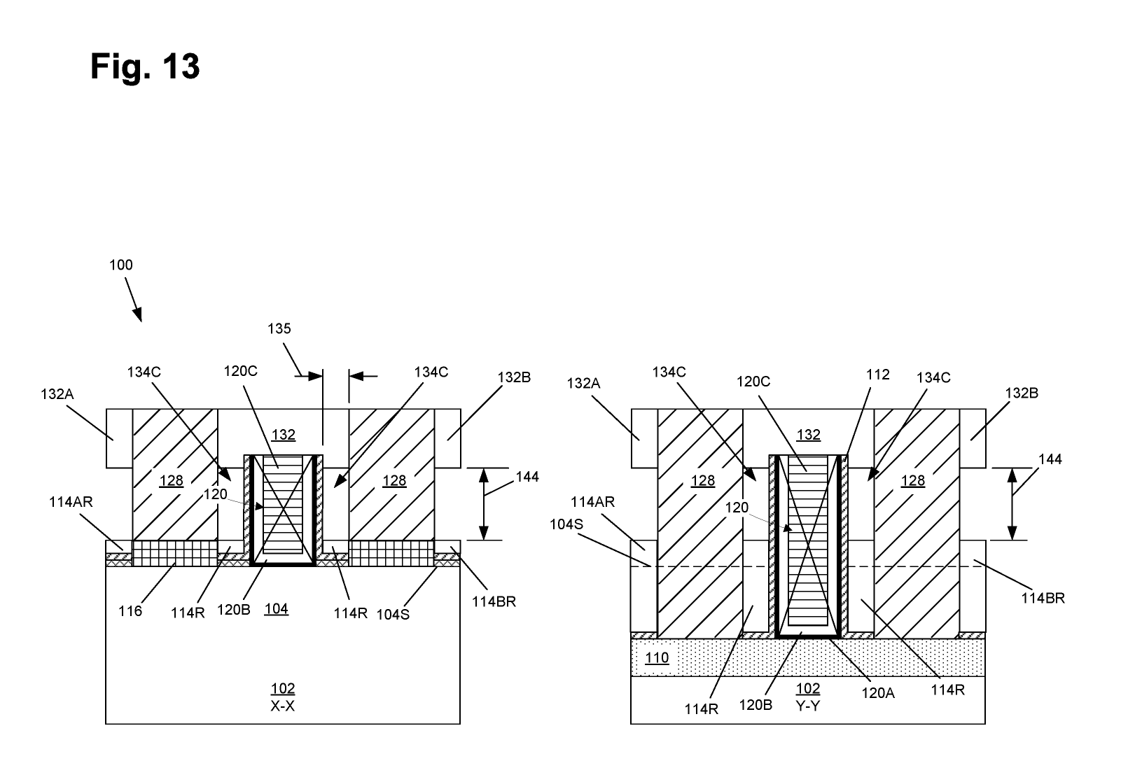

FIG. 13 depicts an alternative embodiment of the device 100 disclosed herein. In this embodiment, instead of removing the entirety of the spacer 114, the spacer 114 is only recessed so as to form a recessed spacer 114R. Recessed spacers 114AR and 114BR on adjacent devices are also depicted. This results in the formation of an air gap 134C that has a substantially uniform height 144 above the fin 104 as well as above the isolation material 110. The magnitude of the dimension 144 depends upon the amount of recessing of the spacer 114. The air gap 134C is bounded laterally above the active region by the side surfaces 120X of the bulk conductive material 120C and the side surfaces 128X of the conductive source/drain contact structures 128.

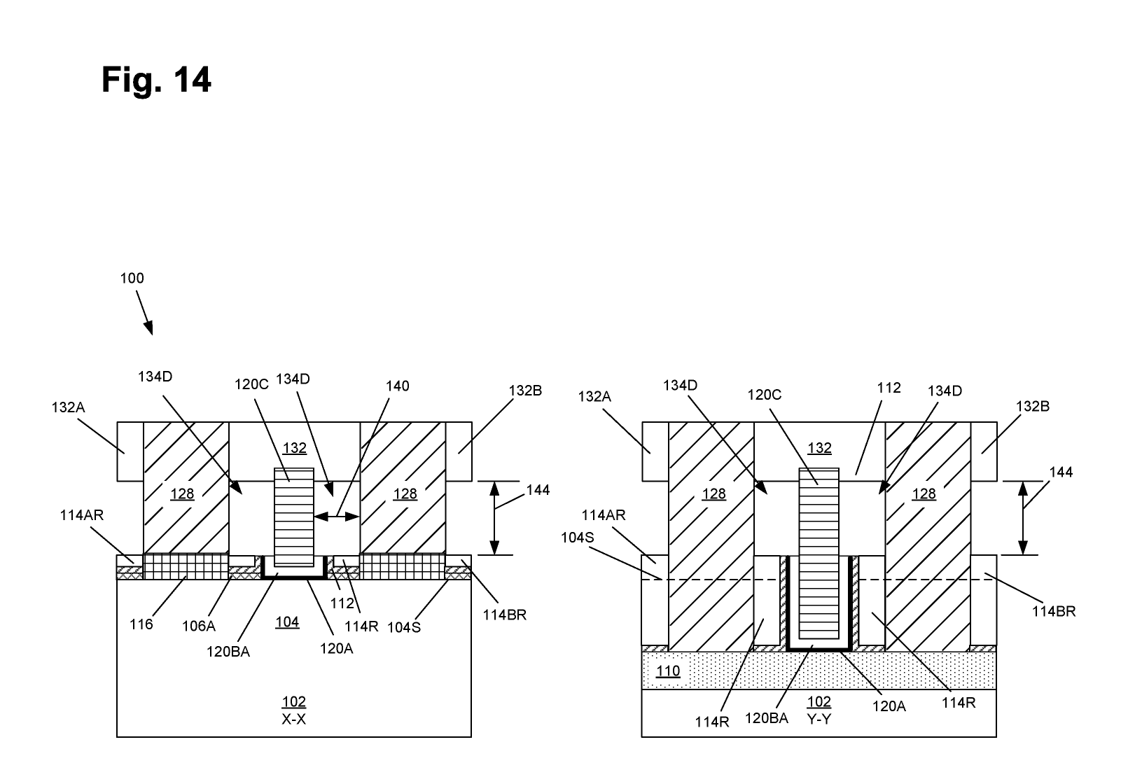

FIG. 14 depicts an alternative embodiment of the device 100 disclosed herein that is very similar to that described above with respect to FIG. 11. In this embodiment, relative to the device shown in FIG. 11, the spacer 114 was recessed (as described above with respect to FIG. 13) and not completely removed, i.e., the recessed spacer 114 was formed. As depicted, in this embodiment, the etch stop layer 112 and all of the gate materials except the bulk conductive material 120C may be recessed by any desired amount. As shown in FIG. 14, this results in the formation of an air gap 134D that is bounded laterally above the active region by the side surface 120X of the bulk conductive material 120C and the side surface 128X of the conductive source/drain contact structures 128. This air gap 134D has approximately the same lateral width 140 as the device shown in FIG. 11. Also note that, due to the recessing of the spacer, the air gap 134D has a substantially uniform height 144 above the fin 104 as well as above the isolation material 110. Although this air gap 134D does not have the “stepped” configuration, it still provides significant benefits relative to prior art method and devices as noted above with respect to the air gap 134C.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Note that the use of terms, such as “first,” “second,” “third” or “fourth” to describe various processes or structures in this specification and in the attached claims is only used as a shorthand reference to such steps/structures and does not necessarily imply that such steps/structures are performed/formed in that ordered sequence. Of course, depending upon the exact claim language, an ordered sequence of such processes may or may not be required. Accordingly, the protection sought herein is as set forth in the claims below.

1. A FinFET device, comprising:
a fin;
a gate structure positioned above a portion of said fin and above an isolation material formed adjacent said fin, said gate structure comprising a conductive material, a work function adjusting layer, and a gate insulation layer, wherein said gate insulation layer and said work function adjusting layer cover a first portion of a side surface of said conductive material and do not cover an exposed second portion of said side surface of said conductive material, wherein a vertical dimension of said second portion above said fin is greater than a vertical dimension of said first portion above said fin;
first and second conductive source/drain contact structures, each comprising a side surface positioned proximate said gate structure; and
a gate cap positioned above said gate structure and contacts said first and second conductive source/drain contact structures, wherein an air gap is formed at least on opposite sides of said gate structure above an active region of said device, said air gap being vertically bounded by at least a bottom surface of said gate cap, an upper surface of said gate insulation layer and said work function adjusting layer covering said first portion of said side surface of said conductive material and an upper surface of said isolation material, said air gap being laterally bounded on a first side by said exposed second portion of said side surface of said conductive material and on a second side by one of a sidewall spacer positioned adjacent said side surfaces of said first and second conductive source/drain contact structures or said side surfaces of said first and second conductive source/drain contact structures.

2. The device of claim 1, wherein said gate insulation layer comprises a high-k (k value greater than 10) gate insulation layer, further comprising an etch stop layer positioned on and in contact with said high-k gate insulation layer.

3. The device of claim 2, wherein said high-k gate insulation layer and said etch stop layer are comprised of different high-k materials.

4. (canceled)

5. The device of claim 1, wherein said air gap has a first vertical dimension at locations above said fin and a second vertical dimension at locations where said gate structure is positioned above said isolation material, said second vertical dimension being greater than said first vertical dimension.

6. The device of claim 1, wherein said air gap has a stepped configuration with portions of said air gap having different vertical dimensions above said fin and above said isolation material.

7. A method of forming a FinFET device, comprising:
forming a fin;
forming an isolation material adjacent said fin;
forming a sidewall spacer around a portion of said fin and above said isolation material;
forming a gate structure adjacent said sidewall spacer comprising a conductive material, a work function adjusting layer, and a gate insulation layer;
forming first and second conductive source/drain contact structures adjacent said sidewall spacer, each of said first and second conductive source/drain contact structures comprising a side surface positioned proximate said sidewall spacer;
after forming said first and second conductive source/drain contact structures, removing at least a first portion of said gate insulation layer and a second portion of said work function adjusting layer, wherein remaining portions of said gate insulation layer and said work function adjusting layer cover a first portion of a side surface of said conductive material and do not cover an exposed second portion of said side surface of said conductive material, wherein a vertical dimension of said second portion above said fin is greater than a vertical dimension of said first portion above said fin; and
forming a gate cap that is positioned above said gate structure for said device, said gate cap contacting said first and second conductive source/drain contact structures, wherein an air gap is formed at least on opposite sides of said gate structure above an active region of said device, said air gap being vertically bounded by at least a bottom surface of said gate cap, an upper surface of said remaining portions of said gate insulation layer and said work function adjusting layer covering said first portion of said side surface of said conductive material and an upper surface of said isolation material, said air gap being laterally bounded on a first side by at least said exposed second portion of said side surface of said conductive material and on a second side by one of said sidewall spacer or said side surfaces of said first and second conductive source/drain contact structures.

8. The method of claim 7, wherein, prior to forming said sidewall spacer, the method comprises:
forming a sacrificial gate electrode structure that is formed around said fin and above said isolation material;
forming a conformal etch stop layer on all side surfaces of said sacrificial gate electrode structure, and wherein said sidewall spacer is formed on and in contact with said conformal etch stop layer; and
removing a portion of said conformal etch stop layer formed over said first portion of said gate insulation layer.

9. The method of claim 8, wherein said gate insulation layer comprises a high-k (k value greater than 10) gate insulation layer and said conformal etch stop layer comprises a high-k material, wherein said conformal etch stop layer is positioned on and in contact with said high-k gate insulation layer.

10. The method of claim 9, wherein said high-k gate insulation layer and said conformal etch stop layer are comprised of different high-k materials.

11. (canceled)

12. The method of claim 7, further comprising, after forming said first and second conductive source/drain contact structures, removing at least a portion of said sidewall spacer, wherein said air gap has a first vertical dimension at locations where said gate structure is positioned above said fin and a second vertical dimension at locations where said gate structure is positioned above said isolation material, said second vertical dimension being greater than said first vertical dimension.

13. The method of claim 7, further comprising, after forming said first and second conductive source/drain contact structures, removing at least a portion of said sidewall spacer, wherein said air gap has a stepped configuration with portions of said air gap having different vertical dimensions above said fin and above said isolation material.

14. The method of claim 7, further comprising, after forming said first and second conductive source/drain contact structures, removing at least a portion of said sidewall spacer, wherein removing said at least a portion of said sidewall spacer comprises removing an entirety of the vertical height of said sidewall spacer at locations above said fin and at locations above said isolation material.

15. The method of claim 7, further comprising, after forming said first and second conductive source/drain contact structures, removing at least a portion of said sidewall spacer, wherein removing said at least a portion of said sidewall spacer comprises removing a first amount of the vertical height of said sidewall spacer at locations above said fin and at locations above said isolation material.

16. A method of forming a FinFET device, comprising:
forming a sacrificial gate electrode structure around a fin and above isolation material positioned adjacent said fin;
forming a first gate cap above said sacrificial gate electrode structure;
forming a conformal etch stop layer on and in contact with all side surfaces of said sacrificial gate electrode structure;
forming a sidewall spacer on and in contact with said conformal etch stop layer;
removing said first gate cap and said sacrificial gate electrode structure so as to define a replacement gate cavity that exposes a portion of said fin, said replacement gate cavity being laterally bounded by said conformal etch stop layer;
forming a replacement gate structure in said replacement gate cavity and a second gate cap above said replacement gate structure, said replacement gate structure comprising a conductive material, a work function adjusting layer, and a gate insulation layer;
forming first and second conductive source/drain contact structures adjacent said sidewall spacer;
after forming said first and second conductive source/drain contact structures, performing at least one etching process to remove said second gate cap, at least a portion of said sidewall spacer so as to expose said conformal etch stop layer and side surfaces of said conductive source/drain contact structures;
removing portions of said conformal etch stop layer, said gate insulation layer, and said work function adjusting layer, wherein remaining portions of said gate insulation layer and said work function adjusting layer cover a first portion of a side surface of said conductive material and do not cover an exposed second portion of said side surface of said conductive material, wherein a vertical dimension of said second portion above said fin is greater than a vertical dimension of said first portion above said fin; and
forming a final gate cap above said replacement gate structure and between said side surfaces of said conductive source/drain contact structures so as to define an air gap on opposite lateral sides of said replacement gate structure above an active region of said device, said air gap being vertically bounded by at least a bottom surface of said final gate cap, an upper surface of said remaining portions of said gate insulation layer and said work function adjusting layer covering said first portion of said side surface of said conductive material and an upper surface of said conformal etch stop material, said air gap being laterally bounded on a first side by said side surfaces of said conductive material and said side surfaces of said first and second conductive source/drain contact structures.

17. (canceled)

18. The method of claim 16, wherein said air gap has a first vertical dimension at locations where said replacement gate structure is positioned above said fin and a second vertical dimension at locations where said replacement gate structure is positioned above said isolation material, said second vertical dimension being greater than said first vertical dimension.

19. The method of claim 16, wherein said air gap has a stepped configuration with portions of said air gap having different vertical dimensions above said fin and above said isolation material.

20. The method of claim 16, wherein said gate insulation layer comprises a high-k (k value greater than 10) gate insulation layer and said conformal etch stop layer comprises a high-k material, wherein said conformal etch stop layer is positioned on and in contact with said high-k gate insulation layer and wherein said high-k gate insulation layer and said conformal etch stop layer are comprised of different high-k materials.

21. The device of claim 1, wherein said air gap has a first vertical dimension at locations above said fin and a second vertical dimension at locations where said gate structure is positioned above said isolation material, said second vertical dimension being equal to said first vertical dimension.

22. The device of claim 1, further comprising an etch stop layer positioned on and in contact with said gate insulation layer formed above said first portion of said side surface of said conductive material.

23. The method of claim 16, wherein said air gap has a first vertical dimension at locations above said fin and a second vertical dimension at locations where said gate structure is positioned above said isolation material, said second vertical dimension being equal to said first vertical dimension.
